(19) United States
(12) Patent Application Publication
(10) Pub. No.: US 2026/0305267 A1
(43) Pub. Date: Oct. 1, 2026

(54) METHOD FOR MANUFACTURING SEMICONDUCTOR DEVICE

(71) Applicant: MITSUBISHI ELECTRIC CORPORATION, Tokyo (JP)

(72) Inventor: Koichiro NISHIZAWA, Tokyo (JP)

(73) Assignee: MITSUBISHI ELECTRIC CORPORATION, Tokyo (JP)

(21) Appl. No.: 19/489,885

(22) PCT Filed: Oct. 25, 2023
(86) PCT No.: PCT/JP2023/038548

§ 371 Date: Dec. 3, 2025

(51) Int. Cl. H10P 76/40; H10P 50/00; H10P 50/24; H10P 50/26

(52) U.S. Cl. CPC H10P 76/405; H10P 50/242; H10P 50/246; H10P 50/262; H10P 50/692

(57) ABSTRACT

A base layer (3) and a gold layer (4) are sequentially formed on a semiconductor substrate (1). A resist pattern (5) is formed on the gold layer (4). A plating film (6) is formed on a part of the gold layer (4) not covered by the resist pattern (5). The gold layer (4) and the base layer (3) exposed by removing the resist pattern (5) are etched by ion milling to form a metal mask (8). The semiconductor substrate (1) is plasma-etched using the metal mask (8) to form a via (9). The base layer (3) is at least one metal layer including one metal selected from Ti, Ta, W, Ni, Co, and Nb or an alloy of two or more of these metals. The thickness of the gold layer (4) is 20 nm or less. The thickness of the base layer (3) is 100 nm or more.

### FIELD

The present disclosure relates to a method for manufacturing a semiconductor device.

### BACKGROUND

An SiC single crystal substrate or a GaN single crystal substrate is used in a power device or a high frequency device. When a semiconductor device is manufactured, etching is performed to form a through electrode (via) in the substrate. However, SiC and GaN compounds are stable covalent crystals and highly intractable materials having low reactivity. Hence, a selection ratio with respect to the rate of processing the substrate cannot be obtained with a resist mask, and thus, a metal mask is used (for example, see PTL 1).

When the metal mask is formed by electroplating, it is necessary to secure a power feeding area in a peripheral portion of a wafer. However, a plating film is not formed in the power feeding area. This causes a problem that the peripheral portion of the wafer is etched and damaged when the substrate is etched. Thus, electroless plating is suitable for formation of the metal mask.

Conventionally, titanium (Ti) and gold (Au) are sequentially formed as a seed layer on a substrate, and a resist pattern is formed thereon. Then, a plating film is formed by electroless plating. Then, a seed film which is exposed by removal of the resist is etched, whereby a metal mask is formed. With the use of the metal mask, a via is formed in the substrate by plasma etching. At this time, etching proceeds in plasma by a chemical reaction of an etching gas.

### CITATION LIST

### Patent Literature

[PTL 1] JP 2010-141178 A

### SUMMARY OF THE INVENTION

### Problem to be Solved by the Invention

Conventionally, Au in the seed layer is exposed on a side surface of an opening of the metal mask. If this Au is mixed in via etching, chemical reactivity of the etching gas decreases. Because of this, there is a problem that etching of the via is stopped. The via etching abnormality causes a conduction failure due to a non-penetrating via, which leads to a reduction in yield.

This disclosure has been made to solve the problem as described above, and an object thereof is to obtain a method for manufacturing a semiconductor device which can inhibit a via etching abnormality.

### Solution to Problem

A method for manufacturing a semiconductor device according to the present disclosure includes: forming a base layer on a semiconductor substrate; forming a gold layer on the base layer; forming a resist pattern on the gold layer; forming a plating film on a part of the gold layer not covered by the resist pattern; etching, by ion milling, the gold layer and the base layer exposed by removing the resist pattern to form a metal mask of the base layer, the gold layer, and the plating film which are left; and plasma-etching the semiconductor substrate using the metal mask to form a via, wherein the base layer is a metal layer of at least one layer including one metal selected from Ti, Ta, W, Ni, Co, and Nb or an alloy of two or more of these metals, a thickness of the gold layer is 20 nm or less, and a thickness of the base layer is 100 nm or more.

### Advantageous Effects of Invention

In the present disclosure, when ion milling is performed on the gold layer and the base layer to form the metal mask, the material of the base layer is ejected and adheres again to the sidewall of an etched part, thereby forming the coating film. The thickness of the base layer is 100 nm or more and is sufficiently large whereas the thickness of the gold layer is 20 nm or less; thus, the sidewall of the etched gold layer can be covered with the coating film. As a result of this, Au can be prevented from being mixed in via etching, and therefore, the via etching abnormality can be inhibited.

### BRIEF DESCRIPTION OF THE DRAWINGS

FIG. 1 is a cross-sectional view showing a method for manufacturing a semiconductor device according to an embodiment.

FIG. 2 is a cross-sectional view showing a method for manufacturing a semiconductor device according to an embodiment.

FIG. 3 is a cross-sectional view showing a method for manufacturing a semiconductor device according to an embodiment.

FIG. 4 is a cross-sectional view showing a method for manufacturing a semiconductor device according to an embodiment.

FIG. 5 is a cross-sectional view showing a method for manufacturing a semiconductor device according to an embodiment.

FIG. 6 is a cross-sectional view showing a method for manufacturing a semiconductor device according to an embodiment.

FIG. 7 is a cross-sectional view showing a method for manufacturing a semiconductor device according to an embodiment.

FIG. 8 is a cross-sectional view showing a method for manufacturing a semiconductor device according to an embodiment.

FIG. 9 is a cross-sectional view showing a method for manufacturing a semiconductor device according to an embodiment.

FIG. 10 is a cross-sectional view showing a method for manufacturing a semiconductor device according to an embodiment.

FIG. 11 is a cross-sectional view showing a method for manufacturing a semiconductor device according to an embodiment.

### DESCRIPTION OF EMBODIMENTS

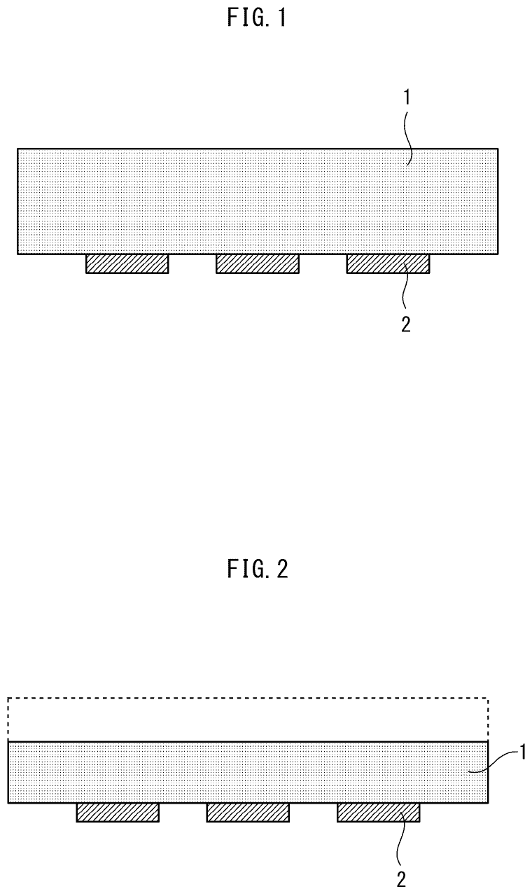

FIGS. 1 to 11 are cross-sectional views showing a method for manufacturing a semiconductor device according to an embodiment. First, as shown in FIG. 1, a plurality of via receiving pads 2 are formed on a front surface of a semiconductor substrate 1 by sputtering, vapor deposition, plating, or the like with spacing therebetween. The semiconductor substrate 1 is an SiC single crystal substrate or a GaN single crystal substrate. As the via receiving pads 2, Ti, W, or the like that has good adhesion to the semiconductor substrate 1 is formed, and then, a metal such as Au, Ag, or Cu that has high conductivity is formed.

Then, as shown in FIG. 2, grinding and polishing are performed on a back surface of the semiconductor substrate 1 so that the semiconductor substrate 1 is thinned to a thickness on the order of 50 μm to 200 μm. This can improve thermal characteristics and high frequency characteristics. The back surface of the thinned semiconductor substrate 1 is subjected to mirror surface processing.

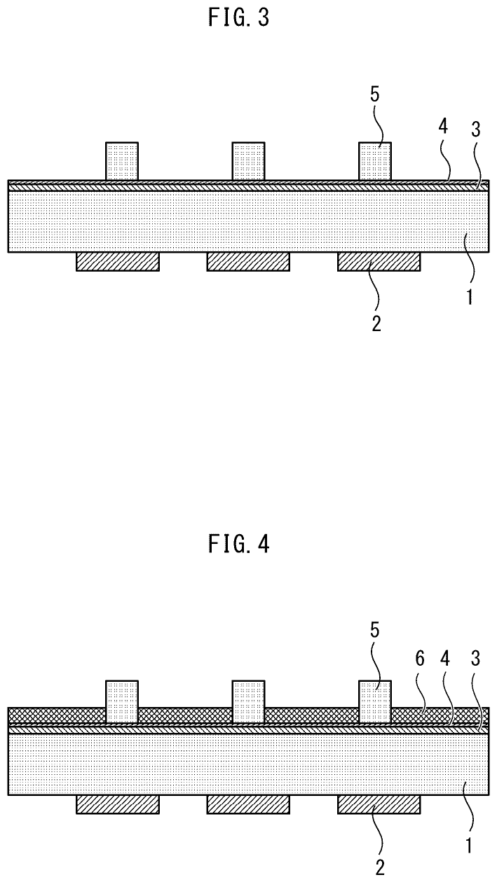

Then, as shown in FIG. 3, a base layer 3 and a gold layer 4 are sequentially formed as a seed layer on the back surface of the semiconductor substrate 1 through continuous film formation by sputtering. The base layer 3 has better adhesion to the semiconductor substrate 1 than the gold layer 4. The gold layer 4 is resistant to surface oxidizing and has high conductivity. A plurality of resist patterns 5 are formed of a photoresist on the gold layer 4 on the back surface side of the substrate so as to face the plurality of via receiving pads 2 on the front surface side of the substrate respectively. Each of the resist patterns 5 has a width narrower than a width of each of the via receiving pads 2.

Then, as shown in FIG. 4, a plating film 6 made of nickel (Ni) or copper (Cu) is formed by electroless plating. Specifically, soaking in a pre-treatment solution is performed to provide a catalyst metal such as Pd on the gold layer 4, and then, soaking into a plating solution is performed. As a result of this, a plating film that is proportional to soaking time is formed. Au itself also catalyzes electroless plating, and therefore, even when tiny amount of Pd is provided, a precipitation reaction of electroless plating can be started stably. Because of this, it is important that a surface to be subjected to electroless plating be a surface of Au.

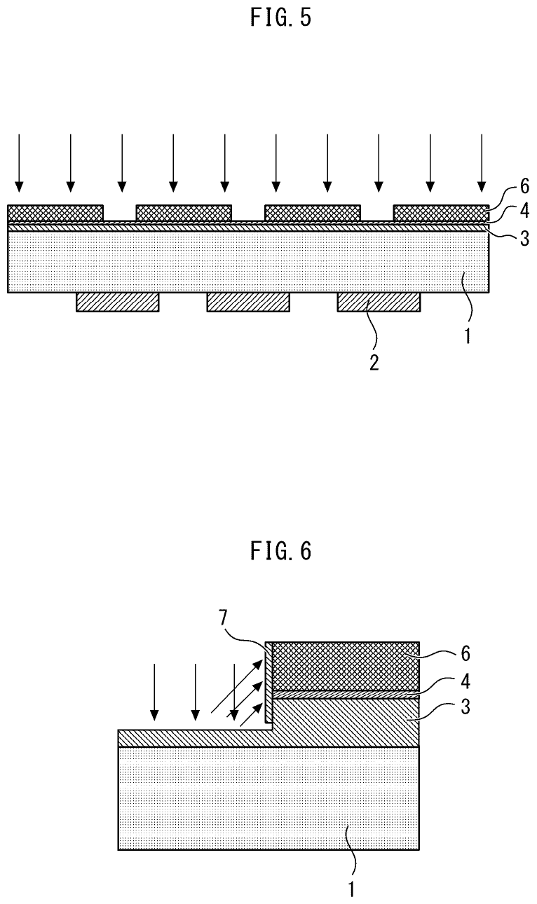

Then, as shown in FIG. 5, the resist patterns 5 are removed. Then, the gold layer 4 is exposed from an opening of the plating film 6. Then, the gold layer 4 and the base layer 3 are etched by ion milling using Ar ions. The acceleration voltage of the ion milling is 600 to 700 V, the current thereof is 400 to 800 mA, the Ar flow rate thereof is 10 to 15 sccm, and the incident angle thereof is perpendicular to the back surface of the substrate. At this time, as shown in FIG. 6, a material of the base layer 3 is ejected by a physical impact of Ar ions and adheres again to a sidewall of the etched gold layer 4; thus, a coating film 7 is formed.

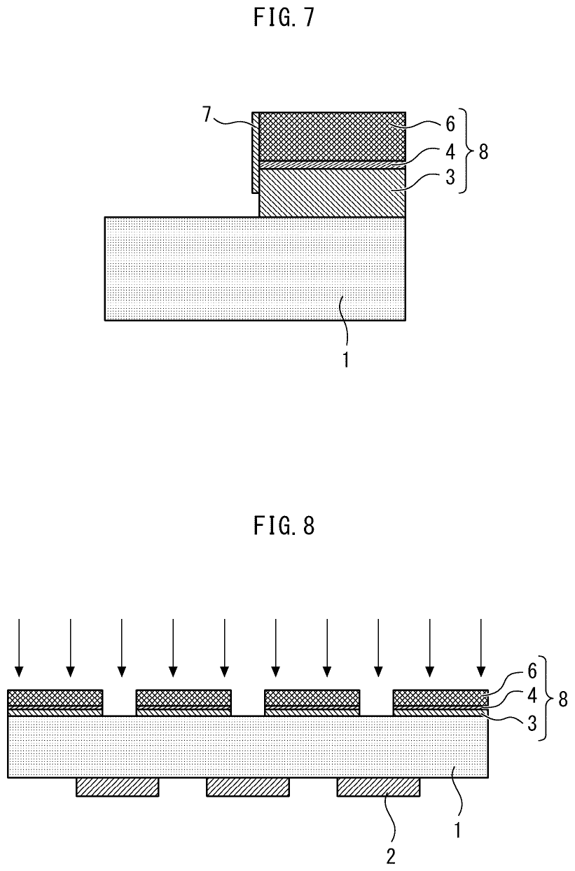

The ion milling is performed until the gold layer 4 and the base layer 3 are penetrated. Thus, as shown in FIG. 7, a metal mask 8 for via etching is formed of the base layer 3, the gold layer 4, and the plating film 6 which are left. On a sidewall of an opening of the metal mask 8, the gold layer 4 is completely covered with the coating film 7 and is not exposed.

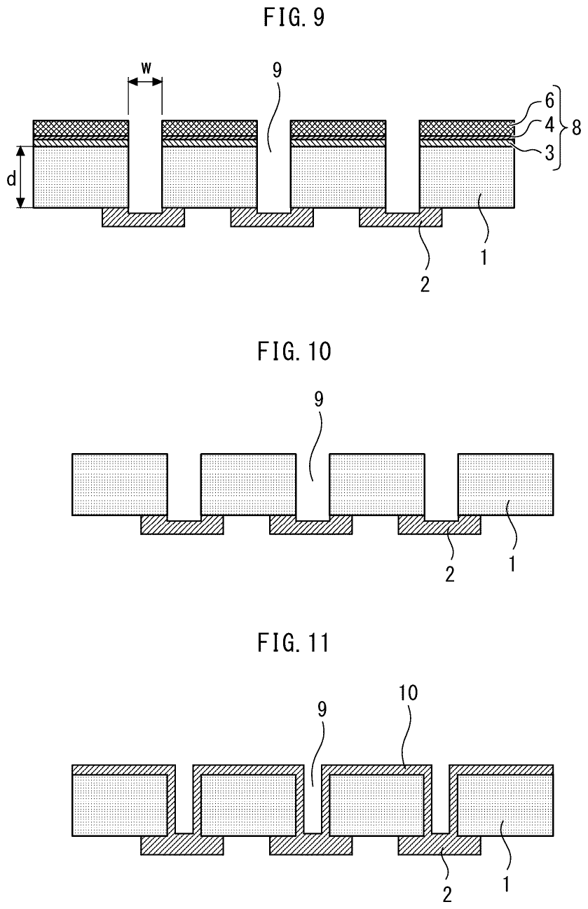

Then, as shown in FIG. 8, the semiconductor substrate 1 is subjected to plasma etching from the back surface side with the use of the metal mask 8. Thus, as shown in FIG. 9, a via 9 that reaches the via receiving pad 2 from the back surface of the semiconductor substrate 1 is formed. The opening of the metal mask 8 and the via 9 each have a width of w, and the via 9 has a depth of d.

The via etching is performed using Inductively Coupled Plasma (ICP), for example. That is, plasma of a gas having reactivity is formed, and the semiconductor substrate 1 is biased, whereby the plasma is drawn to the semiconductor substrate 1. By a chemical reaction and a physical impact between the plasma and the semiconductor substrate 1, etching is performed. As a reactive gas for etching SiC or GaN, SF₆ is used, for example.

Then, as shown in FIG. 10, soaking in an etching solution is performed to remove the metal mask 8. In the case where the plating film 6 is a Ni plating film, nitric acid is used as the etching solution, for example.

Then, as shown in FIG. 11, a back surface electrode 10 that covers the back surface of the semiconductor substrate 1, a side surface of the via 9, and a portion of the via receiving pad 2 which is exposed in the via 9 is formed. As the back surface electrode 10, for example, a Ti film and an Au film are sequentially formed by sputtering, and then, an Au plating film is formed. Since the back surface of the semiconductor substrate 1 is to be subjected to die bonding, the back surface electrode 10 is not subjected to patterning and is formed on the entire back surface of the semiconductor substrate 1. Through the above steps, the semiconductor device according to this embodiment is manufactured.

Table 1 shows the results of evaluating dependence of an occurrence of via etching abnormality on an opening width and a structure of the seed layer. The semiconductor substrate 1 is SiC. The base layer 3 is Ti. The evaluation is performed on the case where the opening of the metal mask 8 is rectangular (20 μm×40 μm) and the depth of the via 9 is 50 μm and the case where the opening of the metal mask 8 is circular (80 μmΦ) and the depth of the via 9 is 100 μm. The term “opening width” refers to a width in a short diameter direction of a rectangular opening of the metal mask 8, i.e., a minimum width of a plane shape of the opening.

TABLE 1

| | Opening | Via | Ti | Au | Via etching |
|---|---|---|---|---|---|
| Sample | width | depth | thickness | thickness | abnormality |
| No. 1 | 20 μm | 50 μm | 50 nm | 100 nm | Occur in 20% |
| | | | | | of wafer plane |
| No. 2 | 20 μm | 50 μm | 50 nm | 20 nm | Occur in 20% |
| | | | | | of wafer plane |
| No. 3 | 20 μm | 50 μm | 100 nm | 20 nm | No occurrence |
| No. 4 | 20 μm | 50 μm | 150 nm | 20 nm | No occurrence |
| No. 5 | 80 μm | 100 μm | 50 nm | 100 nm | No occurrence |
| No. 6 | 80 μm | 100 μm | 50 nm | 20 nm | No occurrence |

The results of the evaluation show that the via etching abnormality does not occur in the case where the opening width is 80 μm, regardless of the Ti thickness and the Au thickness. Thus, it is found that, in the case where the opening is large in size, the influence of Au is small even when Au is involved, and therefore, the via etching abnormality hardly occurs. On the contrary, it can be assumed that the influence of Au on a plasma gas during via etching becomes greater as the opening width is reduced. According to the experiment, in the case where the opening width is 20 μm or less, the via etching abnormality can occur. However, even in the case where the opening width is 20 μm or less, the via etching abnormality does not occur when the Ti thickness is 100 nm or more and the Au thickness is 20 nm or less.

Next, the effect of this embodiment is described while comparing with a comparison example. In the comparison example, the film thickness of the base layer 3 is on the order of 50 nm. Note that since the base layer 3 is formed to ensure adhesion, the thickness to be secured is conventionally considered any as long as uniform film formation can be achieved, and hence, there is no incentive to make the thickness to be 50 nm or more.

As described above, the via etching abnormality hardly occurs in the case where the opening of the metal mask 8 is large in size, but the via etching abnormality occurs in the case where the size of the opening of the metal mask 8 is 20×40=400 μm² or less, i.e., in the case where the minimum width of the opening of the metal mask 8 is 20 μm or less.

As described above, when ion milling is performed on the gold layer 4 and the base layer 3 to form the metal mask 8, the material of the base layer 3 is ejected and adheres again to the sidewall of an etched part, thereby forming the coating film 7. However, in the comparison example, the base layer 3 is thin and therefore the sidewall of the etched gold layer 4 cannot be completely covered with the coating film 7. Owing to this, Au is mixed in via etching, whereby the via etching abnormality occurs.

In response to this, in this embodiment, the thickness of the base layer 3 is 100 nm or more and is sufficiently large whereas the thickness of the gold layer 4 is 20 nm or less; thus, the sidewall of the etched gold layer 4 can be covered with the coating film 7. As a result of this, Au can be prevented from being mixed in via etching, and therefore, the via etching abnormality can be inhibited.

To make the ejected material of the base layer 3 adhere again to the sidewall of the gold layer 4, the material of the base layer 3 needs to have good adhesion to the gold layer 4. However, noble metals such as Pd, Ag, and Pt inhibit via etching in a manner like Au. In view of this, the base layer 3 is formed of a metal layer of at least one layer including one metal selected from Ti, Ta, W, Ni, Co, and Nb or an alloy of two or more of these metals.

In the case where the base layer 3 is thinner than 100 nm, the gold layer 4 cannot not be completely covered with the coating film 7 and the via etching abnormality occurs. In the case where the base layer 3 is thicker than 500 nm, peeling or cracking occurs due to membrane stress. Thus, the thickness of the base layer 3 (a total film thickness of the base layer 3 when the base layer 3 has a laminate structure of a plurality of metal layers) is set to 100 nm or more and 500 nm or less.

In the case where the gold layer 4 is thinner than 5 nm, surface coating is not performed stably and a portion that is not coated with Au is formed, and therefore, a location where the base layer 3 is exposed and the growth of electroless Ni plating is not made is formed. In the case where the gold layer 4 is thicker than 20 nm, the gold layer 4 cannot be completely covered with the coating film 7 and the via etching abnormality occurs. Thus, the thickness of the gold layer 4 is set to 5 nm or more and 20 nm.

In the case where the semiconductor substrate 1 is the SiC substrate or the GaN substrate, a fluorine-based gas such as a SF₆ gas (SF₆+Ar+O₂) is used to perform plasma etching on the semiconductor substrate 1. A chlorine-based gas (Cl₂+BCl₃ or the like) can etch Au also to some extent; however, chemical reactivity of the fluorine-based gas decreases by mixing of Au, in which case inhibition of the via etching abnormality according to this embodiment is effective. The fluorine-based gas is advantageous in having selectivity with respect to a GaN epitaxial layer formed on the surface of the SiC substrate.

Note that the case where via etching is performed from the back surface side of the substrate is described as above. The method of this disclosure is not limited to this and can be applied also to the case where via etching is performed from the front surface side of the substrate to the middle of the substrate and grinding is performed from the back surface side of the substrate.

### REFERENCE SIGNS LIST

1 semiconductor substrate; 3 base layer; 4 gold layer; 5 resist pattern; 6 plating film; 7 coating film; 8 metal mask; 9 via

1. A method for manufacturing a semiconductor device comprising:
forming a base layer on a semiconductor substrate;
forming a gold layer on the base layer;
forming a resist pattern on the gold layer;
forming a plating film on a part of the gold layer not covered by the resist pattern;
etching, by ion milling, the gold layer and the base layer exposed by removing the resist pattern to form a metal mask of the base layer, the gold layer, and the plating film which are left; and
plasma-etching the semiconductor substrate using the metal mask to form a via,
wherein the base layer is a metal layer of at least one layer including one metal selected from Ti, Ta, W, Ni, Co, and Nb or an alloy of two or more of these metals,
a thickness of the gold layer is 20 nm or less, and
a thickness of the base layer is 100 nm or more.

2. The method for manufacturing a semiconductor device according to claim 1, wherein a material of the base layer is ejected by the ion milling and adheres again to a sidewall of the etched gold layer to form a coating film.

3. The method for manufacturing a semiconductor device according to claim 2, wherein the gold layer is completely covered with the coating film and is not exposed on a sidewall of an opening of the metal mask.

4. The method for manufacturing a semiconductor device according to claim 1, wherein a minimum width of an opening of the metal mask is 20 μm or less.

5. The method for manufacturing a semiconductor device according to claim 1, wherein e the semiconductor substrate is a SiC substrate or a GaN substrate, and a fluorine-based gas is used to plasma-etch the semiconductor substrate.

6. The method for manufacturing a semiconductor device according to claim 1, wherein the thickness of the base layer is 500 nm or less.

7. The method for manufacturing a semiconductor device according to claim 1, wherein the thickness of the gold layer is 5 nm or more.
